(19) United States
(12) Patent Application Publication
(10) Pub. No.: US 2025/0081352 A1
(43) Pub. Date: Mar. 6, 2025

(54) FILTER COMPONENT AND METHOD FOR PRODUCING A FILTER COMPONENT

(71) Applicant: TDK Electronics AG, Muenchen (DE)

(72) Inventor: Karl Niklas, Koenigsbronn-Itzelbe (DE)

(21) Appl. No.: 18/844,286

(22) PCT Filed: Mar. 3, 2023
(86) PCT No.: PCT/EP2023/055428

§ 371 Date: Sep. 5, 2024

(30) Foreign Application Priority Data
Mar. 17, 2022 (DE) 10 2022 106 274.0

(51) Int. Cl. H05K 1/18; H01R 12/58; H05K 3/30

(52) U.S. Cl. CPC H05K 1/181; H01R 12/585; H05K 3/303; H05K 2201/1006; H05K 2201/10189; H05K 2201/10272; H05K 2203/166

(57) ABSTRACT

In an embodiment a filter component includes a printed circuit board with an electrical circuit arranged thereon, a bus bar and a clamping plug-in connector, wherein the clamping plug-in connector, arranged on the printed circuit board, is electrically connected to the electrical circuit and is configured for electrically contacting the electrical circuit with the bus bar.

### CROSS-REFERENCE TO RELATED APPLICATIONS

This patent application is a national phase filing under section 371 of PCT/EP2023/055428, filed Mar. 3, 2023, which claims the priority of German patent application 102022106274.0, filed Mar. 17, 2022, each of which is incorporated herein by reference in its entirety.

### TECHNICAL FIELD

A filter component and a method for producing a filter component are disclosed.

### BACKGROUND

Filter components, in particular EMC filter components, are used, for example, to at least partially suppress or eliminate unwanted interference signals in current conductors or electrical connecting elements between electronic components. For example, DC/DC converters are used in electrically powered vehicles, which can be a source of unwanted interference signals. In order to avoid negatively influencing or damaging other electronic components, a filter component is arranged in particular between the DC/DC converter and the other electronic components. A filter component is known, for example, from the publication DE 10 2016 110 742 A1.

The electrical connecting elements between the electronic components are formed as bus bars, for example, in order to be able to carry a high operating current. There is an electrical contact between the filter component and the bus bar to dissipate the electrical interference signal. A soldered connection between the bus bar and the filter component is not possible, for example, due to strong soldering heat dissipation. Therefore, the electrical contact between the bus bar and the filter component is made, for example, by a screw connection.

### SUMMARY

Embodiments provide an improved filter component comprising a particularly compact design.

Further embodiments provide a method for producing a filter component, in which the filter component is designed to be particularly compact.

According to an embodiment, the filter component comprises a printed circuit board with an electrical circuit applied thereon. The electrical circuit is, for example, a low-pass filter configured for filtering high-frequency interference signals. In particular, the electrical circuit comprises several electronic components, for example electrical resistors and capacitors. Furthermore, the electrical circuit comprises at least one terminal contact and one ground contact. The electronic components as well as the terminal contact and the ground contact are preferably electrically connected to each other via conductor tracks on the printed circuit board.

According to a further embodiment, the filter component comprises a bus bar. The bus bar is configured, in particular, for carrying a high electrical operating current. For example, the bus bar is designed for a continuous or variable operating current of at least 50 amperes. The bus bar is, for example, a flat conductor and preferably comprises at least one flat surface that is configured for forming a drilled hole in the bus bar. For example, the bus bar comprises a rectangular or square cross-sectional area.

In particular, the bus bar comprises an electrically conductive material with a low electrical resistance. For example, the bus bar comprises a metal or is made of a metal, for example copper or aluminum.

According to a further embodiment, the filter component comprises a clamping plug-in connector. The clamping plug-in connector is arranged on the printed circuit board, is electrically connected to the electrical circuit and is configured for electrically contacting the electrical circuit with the bus bar. In particular, the clamping plug-in connector is mechanically connected both to the printed circuit board and to the bus bar, and is also electrically conductively connected to the terminal contact of the electrical circuit. Furthermore, the clamping plug-in connector is electrically connected to the bus bar.

The mechanical and electrical connection between the bus bar and the clamping plug-in connector can be reversible or preferably irreversible. For example, the clamping plug-in connector is configured to be plugged onto or into the bus bar and thereby fixes the bus bar in a mechanically clamping manner. The clamping plug-in connector advantageously comprises a more compact design than, for example, a screw connection between the printed circuit board and the bus bar.

According to a further embodiment of the filter component, the clamping plug-in connector comprises an electrically conductive pin that is pressed into a hole in the bus bar, such that a force-locked, electrically conductive connection is established between the electrically conductive pin and the bus bar. The electrically conductive pin comprises, for example, a metal or is made of a metal. In particular, the electrically conductive pin is configured for a press-fit connection with the bus bar.

The electrically conductive pin can be locally welded to the bus bar by applying high pressure when pressing it in. This can also create a material bond between the electrically conductive pin and the bus bar.

A cross-sectional area of the hole in the bus bar may comprise the same or a different shape as a cross-sectional area of the electrically conductive pin. In other words, the electrically conductive pin and the hole comprise the same or different cross-sectional contours. For example, the hole has a circular or an oval cross-sectional area, while the electrically conductive pin may comprise a circular, rectangular or square cross-sectional area. For example, by pressing an electrically conductive pin with a rectangular cross-sectional area into a circular hole, good contact can be advantageously achieved at a comparatively low pressing pressure.

Preferably, the metal pin and/or the hole in the bus bar is deformed during press-in such that there is a permanent, mechanical and electrically conductive connection between the metal pin and the bus bar. In particular, a maximum diameter of the electrically conductive pin in a contact region with the bus bar before press-fitting is slightly larger than a maximum diameter of the hole in the bus bar. Here and in the following, the maximum diameter refers, in particular, to a linear extension of the cross-sectional area in a direction in which the linear extension is largest. For example, the maximum diameter of the electrically conductive pin in the contact region is one to ten percent larger than the maximum diameter of the hole. Pressing the electrically conductive pin into the hole thus creates a low-resistance, electrically conductive and mechanical connection.

The hole in the bus bar can, for example, be a through hole or a blind hole. The blind hole does not penetrate the bus bar completely, while the through hole penetrates the bus bar completely.

The cross-sectional area of the electrically conductive pin is preferably smaller than the cross-sectional area of the bus bar. The electrically conductive pin is configured to conduct an electrical current of the interference signal. The electrical current of the interference signal is, for example, many times smaller than the operating current carried by the bus bar. In particular, the cross-sectional area of the electrically conductive pin can be adapted to the small electrical current of the interference signal.

According to a further embodiment of the filter component, the electrically conductive pin is plastically or elastically deformable in the contact region with the bus bar. For example, the electrically conductive pin is slotted in the contact region, such that the cross-sectional area of the electrically conductive pin is larger in the contact region than in the remaining region of the electrically conductive pin. The electrically conductive pin that is pressed into the hole is in particular plastically or elastically deformed in the contact region, whereby a force-locked and electrically conductive connection is established between the bus bar and the clamping plug-in connector.

According to a further embodiment of the filter component, the electrically conductive pin is pressed into a plated through-hole in the printed circuit board, such that a force-locked, electrically conductive connection is established between the electrically conductive pin and the plated through-hole.

The plated through-hole is, in particular, a hole in the printed circuit board. This hole is lined with an electrically conductive material, whereby the electrically conductive material is electrically connected to the electrical circuit via conductor tracks on the printed circuit board, for example. Preferably, in a contact region with the plated through-hole the electrically conductive pin is formed similarly as in the contact region with the bus bar. In particular, the electrically conductive pin pressed into the plated through-hole is plastically deformed in the contact region with the plated through-hole, so that a low-resistance, electrically conductive and mechanical connection exists between the electrically conductive pin and the plated through-hole.

According to a further embodiment of the filter component, the electrically conductive pin comprises at least one element for limiting the press-in depth. In particular, the element for limiting the press-in depth is designed as a depth stopper. The element for limiting the press-in depth can be formed on a side of the electrically conductive pin facing the bus bar and/or on a side of the electrically conductive pin facing the printed circuit board. The element for limiting the press-in depth is configured, in particular, to determine the maximum press-in depth of the electrically conductive pin in the hole in the bus bar and/or in the plated through-hole of the printed circuit board. For example, the depth stopper formed at both ends of the electrically conductive pin can be used to precisely set a distance between the bus bar and the main surface of the printed circuit board. For this purpose, the electrically conductive pin is pressed into both the bus bar and the printed circuit board to the maximum press-in depth, for example, whereby the maximum press-in depth is determined by the depth stopper.

For example, the electrically conductive pin comprises at least one shoulder as a depth stopper, whereby the shoulder rests directly on a surface of the bus bar after the electrically conductive pin has been pressed into the hole in the bus bar. In this way, the shoulder resting on the surface of the bus bar prevents the electrically conductive pin from being pressed even deeper into the hole in the bus bar.

Furthermore, the electrically conductive pin can comprise at least one shoulder as a depth stopper, whereby the shoulder rests directly on the main surface of the printed circuit board after the electrically conductive pin has been pressed into the plated through-hole of the printed circuit board. In particular, the shoulder resting on the main surface of the printed circuit board prevents the electrically conductive pin from being pressed even deeper into the plated through-hole.

Furthermore, the element for limiting the press-in depth can be configured to arrange the plastically or elastically deformable region of the electrically conductive pin centrally in the bus bar and/or centrally in the printed circuit board. In other words, the element for limiting the press-in depth is configured for ensuring that the plastically or elastically deformable region of the electrically conductive pin is arranged in the center of the bus bar or in the center of the printed circuit board after press-fitting, respectively. For example, the depth stopper prevents the plastic or elastically deformable region of the electrically conductive pin from being pressed through the bus bar or the printed circuit board, respectively. The element for limiting the press-in depth can thus ensure optimum mechanical and electrical contact between the electrically conductive pin and the bus bar or printed circuit board.

According to a further embodiment of the filter component, the two ends of the electrically conductive pin have the same shape. In other words, the electrically conductive pin comprises the same shape and/or the same dimensions on a side facing the bus bar and on a side facing the printed circuit board within production tolerances. As a result, the clamping plug-in connector can be advantageously designed to be particularly compact.

Alternatively, the electrically conductive pin can comprise a different shape and/or different dimensions at the two opposite ends. This means that the shape and/or the dimensions of the electrically conductive pin at the two opposite ends can be adapted to the respective mechanical properties of the bus bar or the printed circuit board, for example.

According to a further embodiment of the filter component, the clamping plug-in connector comprises a spacer that forms a construction space with the printed circuit board and the bus bar. Preferably, the spacer comprises an electrically insulating material or consists of an electrically insulating material. The electrically insulating material is a polymer, for example.

In particular, the bus bar is arranged at a distance from a main surface of the printed circuit board. For example, the spacer determines a distance between the main surface of the printed circuit board and the bus bar. The construction space is, in particular, an intermediate space between the main surface of the printed circuit board and the bus bar. For example, the components of the electrical circuit are arranged in the construction space. The spacer is preferably arranged around the electrically conductive pin and can form an electrical insulation of the electrically conductive pin in the construction space.

The spacer can also be configured for mechanically stabilizing the clamping plug-in connector. For example, the spacer prevents the electrically conductive pin from bending during operation of the filter component or when it is pressed into the bus bar and/or into the printed circuit board.

According to a further embodiment of the filter component, a magnetic toroidal core is arranged in the construction space and surrounds the bus bar. In particular, the magnetic toroidal core is galvanically isolated from the bus bar and the electrical circuit. Furthermore, the magnetic toroidal core is mechanically connected to the printed circuit board, for example via a transport safeguard.

For example, the magnetic toroidal core may comprise an oval or flat-oval form. In other words, the magnetic toroidal core comprises an oval or flat-oval cross-section in a plane perpendicular to the main axis of the magnetic toroidal core. Here and hereinafter, the main axis of the magnetic toroidal core refers to an axis through a center of the magnetic toroidal core that runs along a hole in the magnetic toroidal core. Due to a flat-oval design, a cross-sectional area of the hole in the magnetic toroidal core can be adapted to a rectangular cross-sectional area of the bus bar, for example. This means that the filter component comprises a more compact design.

According to a further embodiment of the filter component, the bus bar is arranged in a plane parallel to a main surface of the printed circuit board. For example, the filter component comprises at least two magnetic toroidal cores that are arranged coaxially on the printed circuit board so that the bus bar penetrates the magnetic ring cores along the common main axis. Here, the main axis of the magnetic ring cores is arranged parallel to the main surface of the printed circuit board.

According to a further embodiment of the filter component, the cross-sectional area of the bus bar is at least 5 square millimeters. In particular, the cross-sectional area of the bus bar is so large that it is not possible to make electrical contact between the bus bar and the electrical circuit by means of a soldered connection. For example, the soldering heat dissipation through the bus bar is so large that it is not possible to form a soldered connection.

According to a further embodiment of the filter component, components of the electrical circuit are arranged on a main surface of the printed circuit board that is opposite to the bus bar. In particular, none or only some of the components of the electrical circuit are arranged in the construction space between the bus bar and the printed circuit board. This means, for example, that several magnetic toroidal cores can be arranged in the construction space at a smaller distance and therefore with a higher packing density. This advantageously shortens the overall length of the filter component in a direction parallel to the main extension direction of the bus bar.

According to a further embodiment, the filter component additionally comprises an electrically insulating potting which encloses at least the bus bar, the magnetic toroidal core and the printed circuit board and is configured for mechanically stabilizing the filter component. In particular, only connection regions of the bus bar and ground contacts of the electrical circuit remain free of the electrically insulating potting. Preferably, the electrically insulating potting also encloses magnetic ring cores, which are mechanically attached to the printed circuit board with the transport safeguard, for example. The electrically insulating potting is thus configured, in particular, for a vibration-proof and/or shake-proof mechanical connection of all parts of the filter component, as well as for electrical insulation of the filter component.

Since the potting is configured to mechanically stabilize the filter component, the electrically conductive pin can comprise a particularly small cross-sectional area, which, in particular, is not configured for a permanent mechanical connection between the printed circuit board and the bus bar. Thus, the clamping plug-in connector can comprise a small design, whereby the filter component advantageously has a compact design.

The filter component described herein is used, in particular, for at least partially suppressing electromagnetic interference signals in an electric current flowing through the bus bar during operation of the filter component.

Furthermore, a method for producing a filter component is specified. In particular, the method can be used to produce the filter component described herein. Thus, all features of the filter component are also disclosed for the method for producing the filter component, and vice versa.

According to an embodiment of the method for producing a filter component, the printed circuit board with the electrical circuit and the clamping plug-in connector applied to the printed circuit board is first provided. The clamping plug-in connector is electrically connected to the electrical circuit.

According to a further embodiment of the method, the bus bar is aligned relative to the clamping plug-in connector. In particular, the electrically conductive pin of the clamping plug-in connector and the hole in the bus bar are aligned such that the electrically conductive pin can be pressed into the hole.

According to a further embodiment of the method, the clamping plug-in connector is pressed into the bus bar for establishing an electrical contact between the bus bar and the electrical circuit. In particular, the electrically conductive pin of the clamping plug-in connector is pressed into the hole in the bus bar such that the electrically conductive pin is elastically or plastically deformed in a contact region with the bus bar. This creates a force-locked, mechanical and low-resistance, electrically conductive connection between the bus bar and the clamping plug-in connector.

According to a further embodiment of the method, a magnetic toroidal core is arranged on the printed circuit board and mechanically fixed, and the bus bar is guided through the magnetic toroidal core before being aligned relative to the clamping plug-in connector.

Furthermore, the bus bar is arranged, in particular, parallel to the main surface of the printed circuit board and is guided along the main axis of the magnetic toroidal core through its center. Here, the magnetic toroidal core remains galvanically isolated from the bus bar and the electrical circuit.

The magnetic toroidal core is mechanically connected to the printed circuit board, the spacer and/or other frame parts, preferably via a transport safeguard, after the bus bar is guided through the toroidal core. The transport safeguard is configured for a temporary mechanical fixation, at least until the filter component has been produced. A permanent mechanical connection of the magnetic toroidal core with the printed circuit board is achieved, for example, by an electrically insulating potting with which the filter component is enclosed. The transport safeguard preferably comprises a smaller design than a permanent connecting element. This means that the entire filter component comprises a more compact design.

According to a further embodiment of the method, the filter component is enclosed with the electrically insulating potting after the clamping plug-in connector has been pressed in. The electrically insulating potting comprises, for example, a casting resin and is configured, in particular, for mechanically stabilizing the filter component and to improve heat dissipation.

### BRIEF DESCRIPTION OF THE DRAWINGS

Further advantageous embodiments and further developments of the filter component and of the method for producing a filter component become apparent from the exemplary embodiments described below in connection with the figures.

FIG. 1 shows a schematic sectional view of a filter component according to an exemplary embodiment;

FIGS. 2 to 5 show schematic perspective views of filter components according to various exemplary embodiments;

FIGS. 6 and 7 show schematic sectional views of stages of a method for producing a filter component according to an exemplary embodiment; and

FIG. 8 shows a schematic perspective view of a part of an electrically conductive pin of a filter component according to an exemplary embodiment.

Elements that are identical, similar or have the same effect are marked with the same reference symbols in the figures. The figures and the proportions of the elements shown in the figures are not to be regarded as true to scale. Rather, individual elements may be shown exaggeratedly large or small for better visualization and/or understanding.

### DETAILED DESCRIPTION OF ILLUSTRATIVE EMBODIMENTS

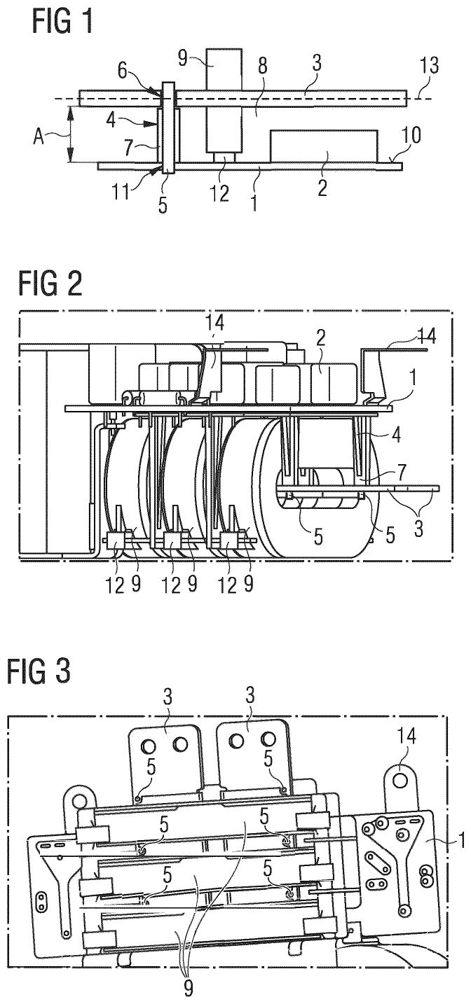

The filter component according to the exemplary embodiment in FIG. 1 comprises a printed circuit board 1 with an electrical circuit 2 applied to it. A clamping plug-in connector 4 establishes a mechanical contact between the printed circuit board 1 and a bus bar 3 running parallel to a main surface 10 of the printed circuit board. Furthermore, the clamping plug-in connector 4 is configured to establish an electrically conductive connection between the bus bar 3 and the electrical circuit 2 on the printed circuit board 1. The electrical circuit 2 is configured for at least partially suppressing interference signals in an electrical current that flows through the bus bar during operation of the filter component.

The clamping plug-in connector 4 comprises an electrically conductive pin 5 and a spacer 7. The spacer 7 partially surrounds the electrically conductive pin 5 and is configured for electrically insulating the electrically conductive pin 5 in an area between the bus bar 3 and the printed circuit board 1. Opposite end regions of the electrically conductive pin 5 are free of the spacer 7 and are configured for electrical contacting of the bus bar 3 and the electrical circuit 2 on the printed circuit board 1. The spacer 7 mechanically stabilizes the electrically conductive pin 5 and prevents the electrically conductive pin 5 from bending.

In particular, the electrically conductive pin 5 is pressed into a hole 6 in the bus bar 3. Here, the hole 6 is formed as a continuous hole 6 that completely penetrates the bus bar 3. Pressing the electrically conductive pin 5 into the hole 6 creates a mechanical, force-locked and electrically conductive connection between the bus bar 3 and the electrically conductive pin 5.

In particular, the electrically conductive pin 5 is plastically or elastically deformable in a contact region with the bus bar 3. For example, the electrically conductive pin 5 is slotted in the contact region and comprises a slightly larger maximum diameter than the hole 6 in the bus bar 3 before it is pressed in.

Furthermore, the electrically conductive pin 5 is mechanically and electrically connected to the printed circuit board 1 via a plated through-hole 11 in the printed circuit board 1. For example, the electrically conductive pin 5 is fixed in the plated through-hole 11 by means of a soldered connection or a press-fit connection.

The spacer 7 is further configured for defining a distance A between the main surface 10 of the printed circuit board 1 and the bus bar 3. In particular, this creates a construction space 8 between the printed circuit board 1 and the bus bar 3. Components of the electrical circuit 2 and a magnetic toroidal core 9 are arranged in the construction space 8. The components of the electrical circuit 2, or at least a part thereof, can also be arranged on a main surface of the printed circuit board 1 facing away from the construction space 8.

The magnetic toroidal core 9 is mechanically fixed to the printed circuit board 1 with a transport safeguard 12 and surrounds the bus bar 3. In particular, the bus bar 3 penetrates the magnetic toroidal core 9 along its main axis 13. The magnetic toroidal core 9 is galvanically isolated from the bus bar 3 and from the electrical circuit 2.

The exemplary embodiment in FIG. 2 shows a filter component which, in contrast to the filter component in FIG. 1, comprises three magnetic ring cores 9 which are arranged coaxially and are mechanically fixed to the printed circuit board 1 by means of transport safeguards 12. The magnetic ring cores 9 enclose two bus bars 3, each of which is connected to the printed circuit board 1 and the electrical circuit 2 arranged thereon via three clamping plug-in connectors 4. The two bus bars 3 are part of a closed circuit, with the electric current in the two bus bars flowing in opposite directions during operation.

Components of the electrical circuit 2 are arranged, in particular, on a main surface of the printed circuit board 1 opposite to the bus bar 3. As a result, the construction space 8 remains free of components of the electrical circuit 2, whereby a higher packing density of the magnetic toroidal cores 9 can be achieved. Thus, the filter component advantageously comprises a small extension in a direction parallel to the main extension direction of the bus bars 3. Ground contacts 14 are configured for external grounding of the filter component.

FIG. 3 shows a further perspective view of the filter component according to the exemplary embodiment in FIG. 2 in a plan view of the main surface 10 of the printed circuit board 1. In particular, FIG. 3 shows the six electrically conductive pins 5 of the clamping plug-in connectors 4, which are pressed into six associated holes 6 in the two bus bars 3.

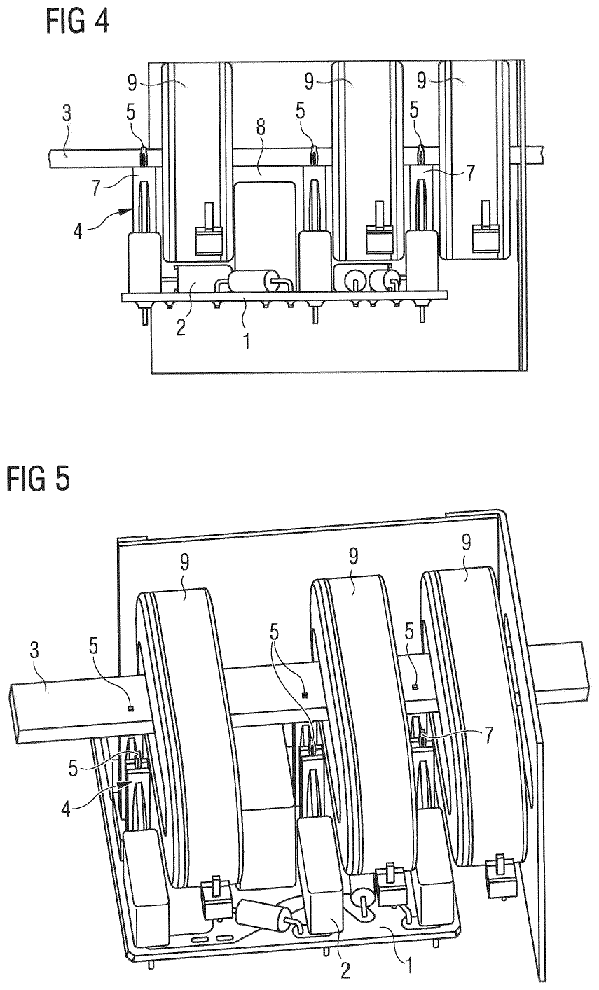

In contrast to the exemplary embodiment of FIGS. 2 and 3, the filter component according to the exemplary embodiment of FIGS. 4 and 5 comprises an electrical circuit 2, the components of which are arranged in the construction space 8 between the bus bar 3 and the printed circuit board 1. In particular, no components of the electrical circuit are arranged on the main surface of the printed circuit board 1 opposite the bus bar 3. As a result, the filter component advantageously comprises a low overall height in a direction perpendicular to the main extension plane of the printed circuit board 1.

FIG. 4 shows a side view of the filter component, while FIG. 5 shows a perspective view, whereby one of the two bus bars 3 is not shown for better visualization. The electrically conductive pins 5 are slotted in the contact region with the bus bar 3. By being pressed into the bus bar 3, the electrically conductive pins 5 are plastically deformed in the slotted area and thus form a particularly good electrical and mechanical contact with the bus bar 3.

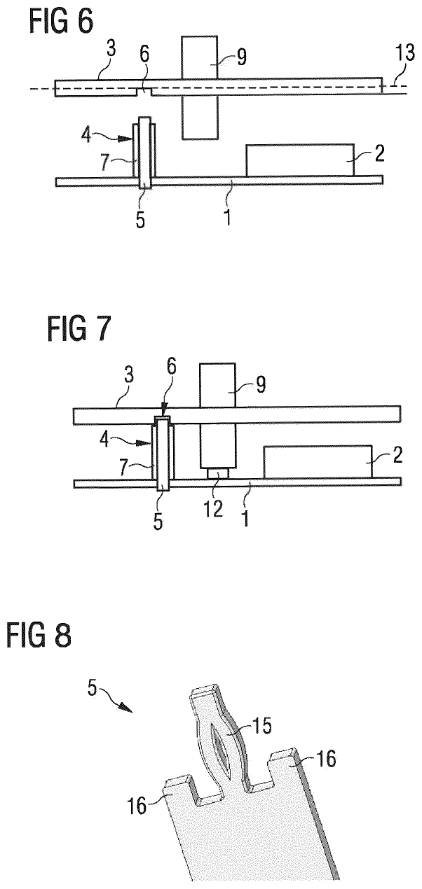

FIG. 6 shows a stage of the filter component after a method step according to an exemplary embodiment, in which the magnetic toroidal core 9 has been pushed onto the bus bar 3 and the bus bar 3 has been aligned relative to the clamping plug-in connector 4. In particular, the bus bar 3 is guided through the magnetic toroidal core 9 parallel to the main axis 13 and aligned in such a way that the electrically conductive pin 5 can be pressed into the hole 6 in the bus bar 3. In particular, the hole 6 in the bus bar 3 is designed as a blind hole that does not fully penetrate the bus bar 3.

FIG. 7 shows a schematic view of the filter component after a further method step, in which the electrically conductive pin 5 of the clamping plug-in connector 4 is pressed into the hole 6 of the bus bar 3 and the magnetic toroidal core 9 is mechanically fixed to the printed circuit board 1 via a transport safeguard 12. For mechanical stabilization and electrical insulation, the filter component is preferably enclosed with an electrically insulating potting in a further method step, whereby in particular only connection areas of the bus bars 3 and ground contacts 14 (not shown here, see for example FIGS. 2 and 3) remain exposed.

The spacer 7 sets a distance between the printed circuit board 1 and the bus bar 3. Furthermore, the spacer 7 mechanically stabilizes the electrically conductive pin 5 and prevents the electrically conductive pin 5 from bending when it is pressed into the bus bar 3. Furthermore, the spacer 7 can determine a press-in depth of the electrically conductive pin 5 in the bus bar 3. In particular, the spacer 7 forms a depth stopper for the electrically conductive pin 5.

FIG. 8 shows one end of an electrically conductive pin 5 of a filter component according to an exemplary embodiment. The electrically conductive pin 5 comprises a mechanically deformable region 15 and a depth stopper 16. The mechanically deformable region 15 is slotted along a longitudinal axis of the electrically conductive pin 5 and is configured to be pressed into a hole 6 in a bus bar 3 (not shown) or into a plated through-hole 11 of a printed circuit board 1 (not shown).

The depth stopper 16 comprises two shoulders, which are arranged next to the mechanically deformable region 15. The depth stopper 16 can also comprise only one shoulder. The two shoulders are arranged offset backwards with respect to the mechanically deformable region 15 in a direction parallel to the longitudinal axis of the electrically conductive pin 5. In particular, the electrically conductive pin 5 can be pressed in up to a press-in depth corresponding to a distance between an end face of the mechanically deformable region 15 and an end face of the depth stopper 16, i.e. an end face of the two shoulders.

The invention is not limited to the description based on the exemplary embodiments. Rather, the invention includes any new feature as well as any combination of features, which includes, in particular, any combination of features in the patent claims, even if this feature or combination itself is not explicitly stated in the patent claims or exemplary embodiments.

1.-16. (canceled)

17. A filter component comprising:
a printed circuit board with an electrical circuit arranged thereon;
a bus bar; and
a clamping plug-in connector,
wherein the clamping plug-in connector, arranged on the printed circuit board, is electrically connected to the electrical circuit and is configured for electrically contacting the electrical circuit with the bus bar.

18. The filter component according to claim 17, wherein the clamping plug-in connector comprises an electrically conductive pin that is pressable into a hole in the bus bar such that a force-locked, electrically conductive connection is established between the electrically conductive pin and the bus bar.

19. The filter component according to claim 18, wherein the electrically conductive pin is plastically or elastically deformable in a contact region with the bus bar.

20. The filter component according to claim 18, wherein the electrically conductive pin is pressable into a plated through-hole in the printed circuit board such that a force-locked, electrically conductive connection is established between the electrically conductive pin and the plated through-hole.

21. The filter component according to claim 18, wherein the electrically conductive pin comprises at least one element configured to limit the press-in depth.

22. The filter component according to claim 17, wherein the clamping plug-in connector comprises a spacer that forms a construction space with the printed circuit board and the bus bar.

23. The filter component according to claim 22, further comprising a magnetic toroidal core arranged in the construction space and surrounding the bus bar.

24. The filter component according to claim 23, further comprising an electrically insulating potting, which encloses at least the bus bar, the magnetic toroidal core and the printed circuit board, and is configured for mechanically stabilizing the filter component.

25. The filter component according to claim 17, wherein the bus bar is arranged in a plane parallel to a main surface of the printed circuit board.

26. The filter component according to claim 17, wherein a cross-sectional area of the bus bar is at least 5 square millimeters.

27. The filter component according to claim 17, wherein components of the electrical circuit are arranged on a main surface of the printed circuit board that is opposite to the bus bar.

28. A method comprising:
at least partially suppressing, by the filter component according to claim 17, electromagnetic interference signals in an electric current flowing through the bus bar.

29. A method for producing a filter component, the method comprising:
providing a printed circuit board with an electrical circuit and a clamping plug-in connector applied to the printed circuit board, wherein the clamping plug-in connector is electrically connected to the electrical circuit;
aligning a busbar relative to the clamping plug-in connector; and
pressing the clamping plug-in connector into the busbar for establishing an electrical contact between the bus bar and the electrical circuit.

30. The method according to claim 29, further comprising:
arranging and mechanically fixing a magnetic toroidal core on the printed circuit board; and
guiding the bus bar through the magnetic toroidal core before being aligned relative to the clamping plug-in connector.

31. The method according to claim 29, further comprising:
sliding at least one magnetic toroidal core onto the bus bar before pressing the clamping plug-in connector into the bus bar; and
subsequently mechanically fixing the magnetic toroidal core with a transport safeguard.

32. The method according to claim 29, further comprising:
enclosing the filter component with an electrically insulating potting after pressing-in the clamping plug-in connector.
